(19) United States
(12) Patent Application Publication
(10) Pub. No.: US 2026/0362764 A1
(43) Pub. Date: Nov. 12, 2026

(54) ISOLATION STRUCTURE FOR SOURCE/DRAIN OF SEMICONDUCTOR DEVICE

(71) Applicant: TAIWAN SEMICONDUCTOR MANUFACTURING CO., LTD., Hsicnhu (TW)

(72) Inventors: Chao-Shuo CHEN, Hsinchu (TW); Chia-Der CHANG, Hsinchu (TW); Yi-Jing LEE, Hsinchu (TW)

(73) Assignee: TAIWAN SEMICONDUCTOR MANUFACTURING CO., LTD., Hsicnhu (TW)

(21) Appl. No.: 19/665,547

(22) Filed: May 1, 2026

Related U.S. Application Data
(63) Continuation of application No. 17/874,171, filed on Jul. 26, 2022, now Pat. No. 12,648,199.
Application No. 17/874,171 is a division of application No. 16/996,647, filed on Aug. 18, 2020, now Pat. No. 11,664,423.

(51) Int. Cl. H10D 62/13; H10D 30/01; H10D 30/62; H10D 62/10; H10D 64/01; H10D 84/01; H10D 84/03; H10P 50/00; H10P 50/24; H10W 10/00; H10W 10/10; H10W 10/17; H10W 20/00

(52) U.S. Cl. CPC H10D 62/151; H10D 30/024; H10D 30/6211; H10D 30/6219; H10D 62/116; H10D 64/0111; H10D 64/01324; H10D 84/013; H10D 84/0135; H10D 84/0151; H10D 84/0158; H10D 84/038; H10P 50/242; H10P 50/691; H10W 10/011; H10W 10/0143; H10W 10/10; H10W 10/17; H10W 20/069

(57) ABSTRACT

The present disclosure describes a semiconductor structure and a method for forming the same. The semiconductor structure can include a substrate, an insulating stack formed over the substrate, a vertical structure formed through the insulating stack, a source/drain region formed over the vertical structure, and an isolation structure formed adjacent to the source/drain region and protruding the insulating stack. The source/drain region can include a first side surface and a second side surface. A lateral separation between the first side surface and the vertical structure can be greater than an other lateral separation between the second side surface and the vertical structure.

### CROSS-REFERENCE TO RELATED APPLICATION

This patent application is a continuation of U.S. patent application Ser. No. 17/874,171, filed on Jul. 26, 2022, and titled “Isolation Structure for Source/Drain of Semiconductor Device,” which is a divisional of U.S. patent application Ser. No. 16/996,647, filed on Aug. 18, 2020, now U.S. Pat. No. 11,664,423, titled “Method for Forming a Source/Drain of a Semiconductor Device having an Insulating Stack in a Recess Structure,” both of which are incorporated by reference herein in their entireties.

### BACKGROUND

Advances in semiconductor technology have increased the demand for transistors with higher performance for high speed applications. To meet this demand, it is essential to minimize the parasitic capacitances associated with the transistors to improve the speed of the integrated circuits. A challenge in improving transistor speed is capacitive coupling among transistor terminals.

### BRIEF DESCRIPTION OF THE DRAWINGS

Aspects of this disclosure are best understood from the following detailed description when read with the accompanying figures. It is noted that, in accordance with the common practice in the industry, various features are not drawn to scale. In fact, the dimensions of the various features may be arbitrarily increased or reduced for clarity of discussion.

FIG. 1A illustrates an isometric view of a semiconductor device, according to some embodiments.

FIGS. 1B-1H illustrate cross-sectional views of a semiconductor device, according to some embodiments.

FIG. 2 is a flow diagram of a method for fabricating a semiconductor device, according to some embodiments.

FIGS. 3A-3D illustrate cross-sectional views of a semiconductor device at various stages of its fabrication process, according to some embodiments.

FIGS. 4A-9A illustrate cross-sectional views of a semiconductor device at various stages of its fabrication process, according to some embodiments.

FIGS. 4B-9B illustrate cross-sectional views of a semiconductor device at various stages of its fabrication process, according to some embodiments.

Illustrative embodiments will now be described with reference to the accompanying drawings. In the drawings, like reference numerals generally indicate identical, functionally similar, and/or structurally similar elements.

### DETAILED DESCRIPTION

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values is typically due to slight variations in manufacturing processes or tolerances.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

As used herein, the term “vertical” means nominally perpendicular to the surface of a substrate.

As used herein, the term “insulating layer” refers to a layer that functions as an electrical insulator (e.g., a dielectric layer).

As used herein, the term “selectivity” refers to the ratio of the etch rates of two materials under a same etching condition.

As used herein, the term “high-k” refers to a dielectric constant that is greater than the dielectric constant of SiO₂ (e.g., greater than 3.9).

As used herein, the term “p-type” defines a structure, layer, and/or region as being doped with p-type dopants, such as boron.

As used herein, the term “n-type” defines a structure, layer, and/or region as being doped with n-type dopants, such as phosphorus.

Fins associated with fin field effect transistors (finFETs) or gate-all-around (GAA) FETs may be patterned by any suitable method. For example, the fins may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Technology advances in the semiconductor industry drive the pursuit of integrated circuits (IC)s having higher performance for high-speed applications. In the course of the IC evolution, raised source/drain (RSD) structures have been adopted in the transistor to provide reduced contact resistance and enhanced channel stress to improve transistor speed. The RSD structure can be formed, for example, by epitaxially growing doped regions adjacent to the transistor's channel region. The epitaxially grown RSD structure can have an extension laterally extending beyond the transistor's width, in which the lateral extension can introduce a parasitic capacitance between the channel region (e.g., gate terminal) and the source/drain region (e.g., source terminal and/or drain terminal), thus degrading the operating speed of the transistor and the IC.

The present disclosure is directed to a fabrication method and a transistor with a source/drain (S/D) structure that has a reduced lateral extension. For example, the S/D structure can be formed over side surfaces of a fin structure, where the S/D structure can be fabricated to reduce its lateral volume extending over the fin structure's side surfaces. In some embodiments, a portion of the S/D structure formed over a side surface of the fin structure can be fabricated with a narrower width than another portion of the S/D structure formed over an opposite side surface of the fin structure. In some embodiments, a portion of the S/D structure formed over a side surface of the fin structure can be fabricated to have an asymmetric shape with respect to another portion of the S/D structure formed over an opposite side surface of the fin structure. In some embodiments, the S/D structure and the transistor's gate structure can be fabricated to reduce the S/D lateral extension and isolate the gate structure from adjacent transistors (e.g., cut metal-gate scheme). A benefit of the present disclosure, among others, is to suppress the parasitic capacitance between the S/D structure and the transistor's gate structure, thus decreasing the RC time delay of the transistor and improving the transistor's operating speed.

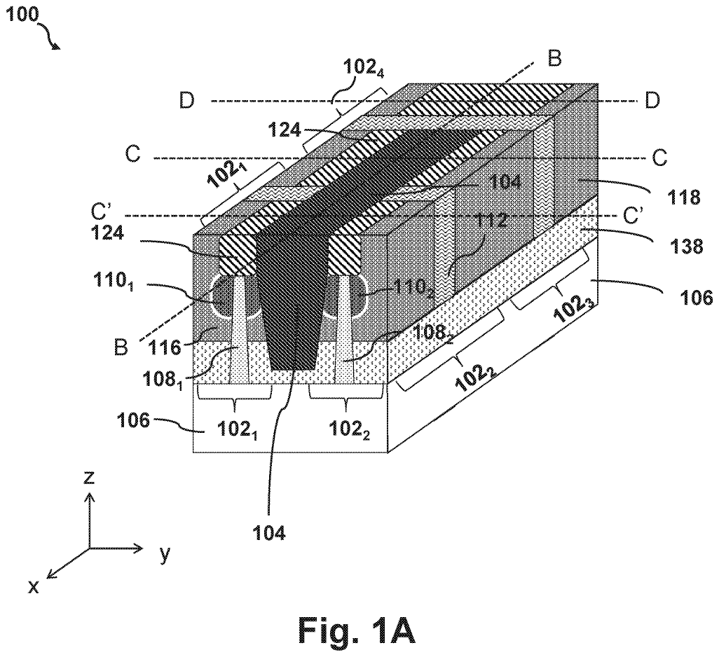

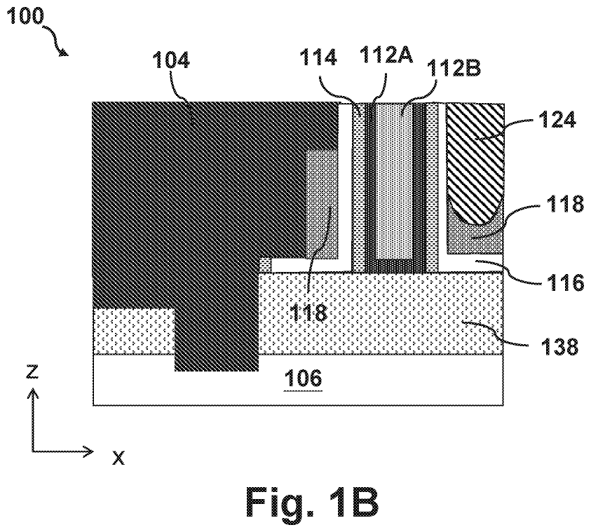

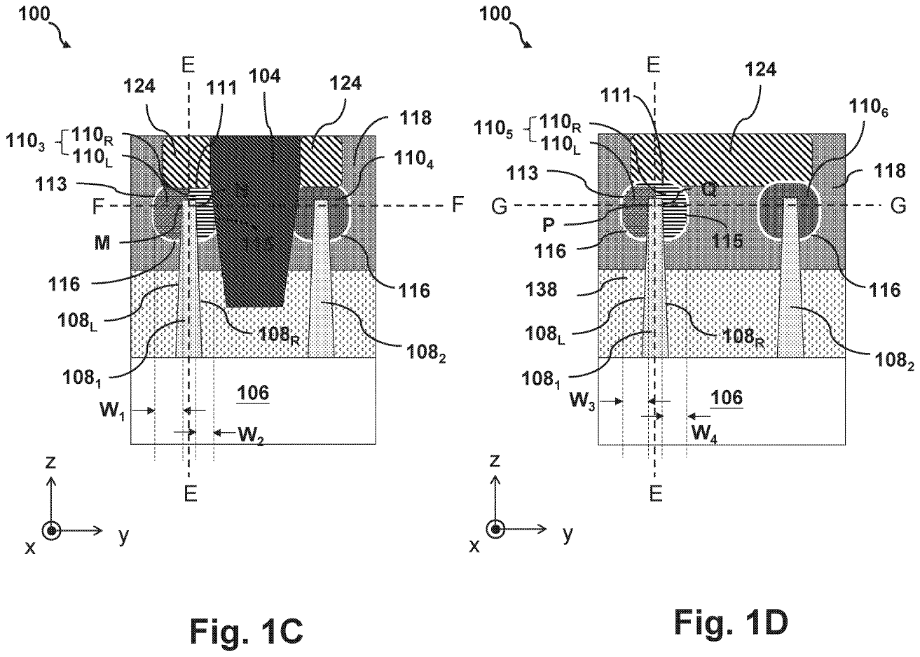

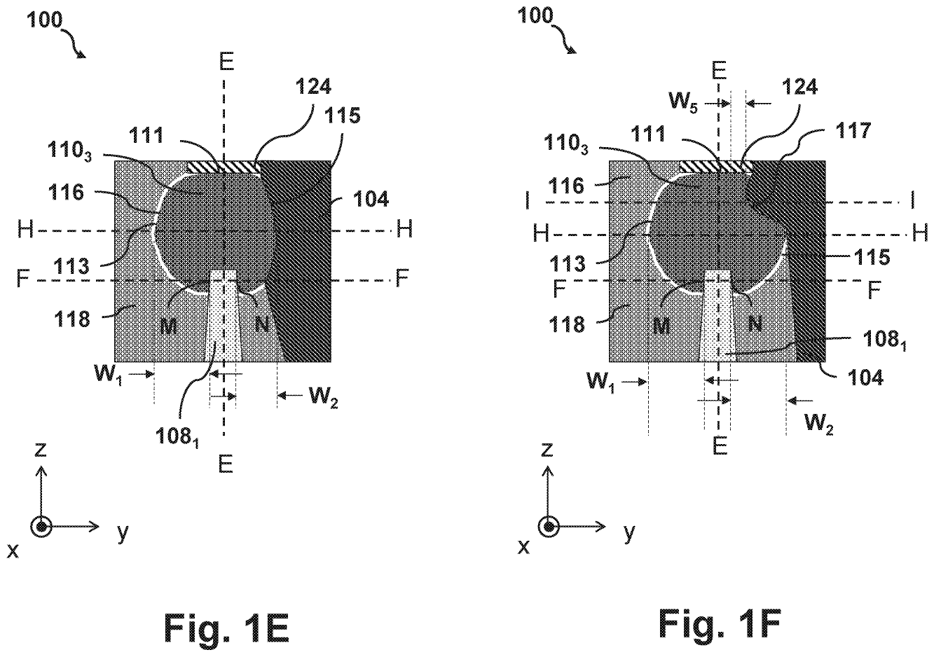

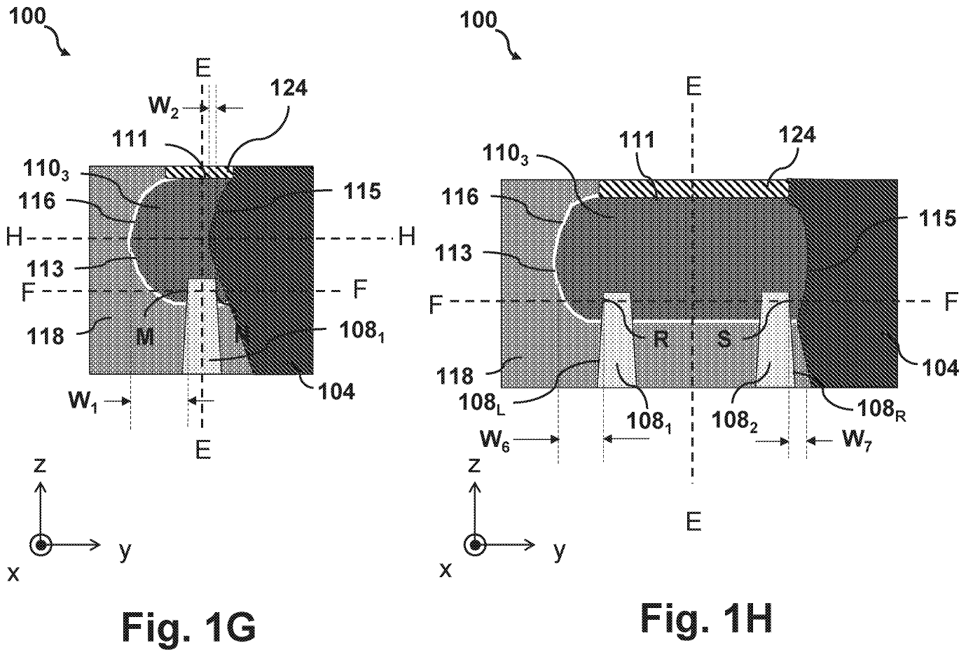

A semiconductor device 100 having a multiple FETs 102 (e.g., FETs 102₁-102₄) formed over a substrate 106 is described with reference to FIGS. 1A-1H, according to some embodiments. FIG. 1A illustrates an isometric view of semiconductor device 100, according to some embodiments. FIG. 1B illustrates a cross-sectional view along line B-B (e.g., along a gate region) of semiconductor device 100, according to some embodiments. FIGS. 1C and 1E-1H illustrate cross-sectional views along lines C-C (e.g., along source/drain (S/D) regions) of semiconductor device 100, according to some embodiments. The cross-sectional view along line C′-C′ in FIG. 1A can be similar to the cross-sectional view in FIG. 1C. FIG. 1D illustrates a cross-sectional view along line D-D (e.g., along source/drain (S/D) regions) of semiconductor device 100, according to some embodiments. Semiconductor device 100 can be included in a microprocessor, memory device, or other integrated circuit (IC). The scale and shapes of various labeled elements in isometric and cross-sectional views of semiconductor device 100 are shown for illustration purposes and not intended to be limiting. Further, the discussion of elements in FIGS. 1A-1H with the same annotations applies to each other, unless mentioned otherwise. Also, though each FET 102 shown in FIGS. 1A-1H is a fin field effect transistor (finFET), each FET 102 can be a gate-all-around (GAA) FET, according to some embodiments.

Referring to FIG. 1A, each FET 102 (e.g., FETs 102₁-102₄) can include a fin structure 108 extending along an x-axis, a gate structure 112 traversing through fin structure 108 along an y-axis, and source/drain (S/D) regions 110 formed over portions of fin structure 108. Although FIG. 1A shows each fin structure 108 accommodating two FETs 102, any number of FETs 102 can be disposed along each fin structure 108. In some embodiments, FET 102 can include multiple fin structures 108 extending along a first horizontal direction (e.g., in the x-direction), and gate structure 112 traversing through the multiple fin structures 108 along a second horizontal direction (e.g., in the y-direction). In some embodiments, multiple FETs 102 (e.g. FETs 102₃ and 102₄) can have a common gate structure 112. In some embodiments, gate structures 112 of multiple FETs 102 (e.g., FETs 102₁ and 102₂) can be isolated from each other by an isolation structure 104.

Substrate 106 can be a semiconductor material such as, but not limited to, silicon. In some embodiments, substrate 106 can include a crystalline silicon substrate (e.g., wafer). In some embodiments, substrate 106 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 106 can be doped depending on design requirements (e.g., p-type substrate or n-type substrate). In some embodiments, substrate 106 can be doped with p-type dopants (e.g., boron (B), indium (In), aluminum (Al), or gallium (Ga)) or n-type dopants (e.g., phosphorus (P) or arsenic (As)).

Each fin structure 108 (e.g., fin structures 108₁ and 108₂) can be formed over substrate 106 and can include a material similar to substrate 106. In some embodiments, fin structure 108 can include a material having a lattice constant substantially close to (e.g., lattice mismatch within 5%) that of substrate 106. In some embodiments, fin structure 108 can include a material identical to substrate 106. In some embodiments, fin structure 108 can include multiple channel layers, each made of identical or different materials from each other.

Semiconductor device 100 can further include shallow trench isolation (STI) regions 138 configured to provide electrical isolation for fin structure 108. For example, STI regions 138 can electrically isolate fin structure 108₁ from fin structure 108₂. STI regions 138 can provide electrical isolation between FETs 102 residing on fin structure 108. Also, STI regions 138 can provide electrical isolation between FETs 102 and neighboring active and passive elements (not shown in FIG. 1A) integrated with or deposited on substrate 106. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials.

Referring to FIGS. 1A and 1B, gate structure 112 can be multi-layered structures that wraps around portions of one or more fin structures 108 to modulate FET 102. For example, gate structure 112 can wrap around portions of fin structures 108₁ to modulate a conductivity of FET 102₁'s channel. In some embodiments, gate structure 112 can be referred to as gate-all-around (GAA) structures, where FET 102 can be referred to as a GAA FET 102. Gate structure 112 can include a gate dielectric layer 112A, a gate electrode 112B disposed on dielectric layer 112A, and gate spacers 114 disposed on sidewalls of gate electrode 112B.

Gate dielectric layer 112A can be wrapped around portions of fin structure 108 and can be further disposed between gate electrode 112B and S/D regions 110 to prevent electrical shorting in between. Gate dielectric layer 112A can include silicon oxide and can be formed by chemical vapor deposition (CVD), atomic layer deposition (ALD), physical vapor deposition (PVD), e-beam evaporation, or other suitable processes. In some embodiments, gate dielectric layer 112A can include (i) a layer of silicon oxide, silicon nitride, and/or silicon oxynitride, (ii) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), (iii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu), or (iv) a combination thereof. High-k dielectric layers can be formed by ALD and/or other suitable methods. In some embodiments, gate dielectric layer 112A can include a single layer or a stack of insulating material layers. Gate dielectric layer 112A can have a thickness ranging from about 1 nm to about 5 nm. Other materials and formation methods for gate dielectric layer 112A are within the scope and spirit of this disclosure.

Gate electrode 112B can function as a gate terminal for FET 102. Gate electrode 112B can include a metal stack wrapping around portions of fin structure 108. In some embodiments, gate electrode 112B can include a gate barrier layer (not shown in FIGS. 1A and 1B), a gate work function layer (not shown in FIGS. 1A and 1B), and a gate metal fill layer (not shown in FIGS. 1A and 1B). The gate barrier layer can serve as a nucleation layer for subsequent formation of a gate work function layer. In some embodiments, the gate barrier layer can prevent a diffusion of metals (e.g., aluminum) from the gate work function layer to underlying layers (e.g., gate dielectric layers 112A). The gate barrier layer can include titanium (Ti), tantalum (Ta), titanium nitride (TiN), tantalum nitride (TaN), or other suitable diffusion barrier materials. The gate work function layer can include a single metal layer or a stack of metal layers. The stack of metal layers can include metals having work function values equal to or different from each other. In some embodiments, the gate work function layer can include aluminum (Al), copper (Cu), tungsten (W), titanium (Ti), tantalum (Ta), titanium nitride (TiN), tantalum nitride (TaN), nickel silicide (NiSi), cobalt silicide (CoSi), silver (Ag), tantalum carbide (TaC), tantalum silicon nitride (TaSiN), tantalum carbon nitride (TaCN), titanium aluminum (TiAl), titanium aluminum nitride (TiAlN), tungsten nitride (WN), metal alloys, and combinations thereof. In some embodiments, the gate work function layer can include Al-doped metal, such as Al-doped Ti, Al-doped TiN, Al-doped Ta, and Al-doped TaN. The gate metal fill layer can include a single metal layer or a stack of metal layers. The stack of metal layers can include metals different from each other. In some embodiments, the gate metal fill layer can include a suitable conductive material, such as Ti, silver (Ag), Al, titanium aluminum nitride (TiAlN), tantalum carbide (TaC), tantalum carbo-nitride (TaCN), tantalum silicon nitride (TaSiN), manganese (Mn), Zr, titanium nitride (TiN), tantalum nitride (TaN), ruthenium (Ru), molybdenum (Mo), tungsten nitride (WN), copper (Cu), tungsten (W), cobalt (Co), nickel (Ni), titanium carbide (TiC), titanium aluminum carbide (TiAlC), tantalum aluminum carbide (TaAlC), metal alloys, and combinations thereof. Other materials for the gate barrier layer, the gate work function layer, and the gate metal fill layer are within the scope and spirit of this disclosure.

Gate spacer 114 can be in physical contact with gate dielectric layers 112A, according to some embodiments. Gate spacer 114 can have a low-k material with a dielectric constant less than about 3.9. For example, gate spacer 114 can include insulating material, such as silicon oxide, silicon nitride, a low-k material, and a combination thereof. In some embodiments, gate spacer 114 can have a thickness ranging from about 2 nm to about 10 nm. Other materials and thicknesses for gate spacer 114 are within the scope and spirit of this disclosure.

Referring to FIGS. 1A, 1C, and 1D, each FET 102 can have S/D regions 110 formed at opposite sides (e.g., along x-direction) of gate structure 112. Each S/D region 110 can include a top surface 111, a side surface 113, and a side surface 115 opposite to side surface 113. Further, each S/D region 110 can be partitioned into lateral S/D portions 110_{L} and 110_{R}. Lateral S/D portions 110_{L} can include side surface 113. Similarly, lateral S/D portion 110_{R} can include side surface 115. In some embodiments, S/D region 110 can be partitioned into lateral S/D portions 110_{L} and 110_{R} by a cross-sectional line E-E that crosses a midpoint of fin structure 108's top. By way of example and not limitation, cross-sectional line E-E can be substantially perpendicular to substrate 106 and can cross a midpoint of fin structure 108 to substantially bisect fin structure 108. In some embodiments, lateral S/D portions 110_{L} and 110_{R} can be respectively formed over fin structure 108's opposite sides. For example, lateral S/D portion 110_{L}'s side surface 113 can be laterally (e.g., in the opposite y-direction) positioned over fin structure 108's side surface 108_{L}. Similarly, lateral S/D portion 110_{R}'s side surface 115 can be laterally (e.g., in the y-direction) positioned over fin structure 108's side surface 108_{R}.

Each S/D region 110 (e.g., S/D regions 110₁-110₆) can include an epitaxially-grown semiconductor material. In some embodiments, the epitaxially grown semiconductor material can be the same material as the material of substrate 106. In some embodiments, the epitaxially-grown semiconductor material can have a lattice constant substantially close to (e.g., lattice mismatch within 5%) that of the material of substrate 106. In some embodiments, the epitaxially-grown semiconductor material can include: (i) a semiconductor material, such as Ge and Si; (ii) a compound semiconductor material, such as GaAs and AlGaAs; or (iii) a semiconductor alloy, such as SiGe and GaAsP. S/D region 110 can be doped with p-type dopants or doped with n-type dopants. The p-type dopants can include B, In, Al, or Ga. The n-type dopants can include P or As. In some embodiments, S/D region 110 can have multiple sub-regions (not shown) that may include SiGe and may differ from each other based on, for example, doping concentration, epitaxial growth process conditions, and/or relative concentration of Ge with respect to Si.

In some embodiments, one of lateral S/D portions 110_{L} and 110_{R} can have a smaller volume than the other. For example, referring to FIG. 1C, S/D region 110₃'s lateral S/D portion 110_{R} can have a smaller volume than S/D region 110₃'s lateral S/D portion 110_{L}. In some embodiments, a ratio of lateral S/D portion 110_{R}'s volume to lateral S/D portion 110_{L}'s volume can be from about 0.05 to about 0.65, from about 0.05 to about 0.6, or from about 0.1 to about 0.5. By way of example and not limitation, the above-noted volume ratio of S/D region 110₃'s lateral S/D portion 110_{L} to lateral S/D portion 110_{R} can be achieved by method 200 (discussed below). Further, since the volume of S/D region 110₃'s lateral S/D portion 110_{R} can be reduced, the overall parasitic capacitance between S/D region 110₃ and gate structure 112 can be reduced, thus enhancing the overall operating speed of FET 102₁ and/or FET 102₄.

In some embodiments, lateral S/D portions 110_{L} and 110_{R} can have a substantially equal volume to each other. For example, referring to FIG. 1D, S/D region 110₅'s lateral S/D portion 110_{R} can have a substantially equal volume to S/D region 110₅'s lateral S/D portion 110_{L}. In some embodiments, a ratio of lateral S/D portion 110_{R}'s volume of S/D region 110₅ to S/D portion 110_{L}'s volume of S/D region 110₅ can be from about 0.5 to about 1.5, from about 0.6 to about 1.4, or from about 0.7 to about 1.3. By way of example and not limitation, the above-noted volume variation between S/D region 110₅'s lateral S/D portions 110_{L} and 110_{R} can be caused by a process variation (e.g., precursor gas flow's fluctuation) associated with an epitaxial growth process that grows S/D region 110's semiconductor material.

In some embodiments, one of lateral S/D portions 110_{L} and 110_{R} can have a reduced side extension (e.g., along the y-direction) compared to the other. For example, referring to FIG. 1C, a cross-sectional line F-F substantially parallel to substrate 106 can cross points M and N over fin structure 108's side surfaces 108_{L} and 108_{R}. A lateral width W₂ between S/D region 110₃'s lateral S/D portion 110_{R}'s side surface 115 and fin structure 108's side surface 108_{R} (e.g., point N) can be narrower than a lateral width W₁ between S/D region 110₃'s lateral S/D portion 110_{L}'s side surface 113 and fin structure 108's side surface 108_{L} (point M). In some embodiments, a difference between lateral widths W₁ and W₂ can be from about 2 nm to about 25 nm, from about 3 nm to about 20 nm, or from about 5 nm to about 15 nm. In some embodiments, a ratio of lateral width W₂ to lateral width W₁ can range from about 0.05 to about 0.75, from about 0.05 to about 0.6, or from about 0.05 to about 0.5. In some embodiments, lateral width W₁ can represent a lateral (e.g., along y-direction) separation between an outermost portion of side surface 113 and side surface 108_{L}, where lateral width W₁ can be from about 5 nm to about 20 nm. In some embodiments, In some embodiments, lateral width W₂ can represent a lateral (e.g., along y-direction) separation between an outermost portion of side surface 115 and side surface 108_{R}, where lateral width W₂ can be from about 2 nm to about 15 nm or from about 2 nm to about 10 nm. By way of example and not limitation, the above-noted lateral extension width difference/ratio between S/D region 110₅'s lateral S/D portions 110_{L} and 110_{R} can be achieved by method 200 (discussed below). Further, since the lateral extension width W₂ of S/D region 110₃'s lateral S/D portion 110_{R} can be reduced, the overall parasitic capacitance between S/D region 110₃ and gate structure 112 can be reduced, thus enhancing the overall operating speed of FET 102₁ and/or FET 102₄.

In some embodiments, lateral S/D portions 110_{L} and 110_{R} can have a substantially equal side extension (e.g., along the y-direction). For example, referring to FIG. 1D, for a cross-sectional line G-G substantially parallel to substrate 106 and crossing points P and Q on fin structure 108's side surfaces 108_{L} and 108_{R}, a lateral width W₃ between S/D region 110₅'s lateral S/D portion 110_{L}'s side surface 113 and fin structure 108's side surface 108_{L} (point M) can be substantially equal to a lateral width W₄ between S/D region 110₅'s lateral S/D portion 110_{R}'s side surface 115 and fin structure 108's side surface 108_{R} (point N). In some embodiments, a difference between lateral widths W₃ and W₄ can be from about 0 nm to about 10 nm or from about 0 nm to about 7 nm. In some embodiments, a ratio of lateral width W₄ to lateral width W₃ can range from about 0.5 to about 1.5, from about 0.6 to about 1.4, or from about 0.7 to about 1.3. In some embodiments, cross-sectional line G-G can substantially and vertically (e.g., in the z-direction) level with cross-sectional line F-F (shown at FIG. 1C), where width W₃, width W₄, and width W₁ (shown at FIG. 1C) can be substantially equal to each other. By way of example and not limitation, the above-noted lateral extension width variation between S/D region 110₅'s lateral S/D portions 110_{L} and 110_{R} can be caused by a process variation (e.g., precursor gas flow's fluctuation) associated with an epitaxial growth process that grows S/D region 110's semiconductor material.

In some embodiments, the shapes of lateral S/D portions 110_{L} and 110_{R} can be substantially asymmetric to each other with respect to cross-sectional line E-E. For example, referring to FIG. 1C, for a cross-sectional line (e.g., cross-sectional line F-F) substantially parallel to substrate 106 and crossing S/D region 110 (e.g., S/D region 110₃), side surface 113 of S/D region 110₃'s lateral S/D portion 110_{L} can include a convex sidewall proximate to the cross-sectional line (e.g., cross-sectional line F-F), while side surface 115 of S/D region 110₃'s lateral S/D portion 110_{R} can include a straight slanting sidewall proximate to the same cross-sectional line (e.g., cross-sectional line F-F). In some embodiments, both the convex sidewall and the straight slanting sidewall can connect S/D region 110₃'s top surface 111 and fin structure 108. By way of example and not limitation, the above-noted shape asymmetry between S/D region 110₃'s lateral S/D portions 110_{L} and 110_{R} can be achieved by method 200 (discussed below).

In some embodiments, the shapes of lateral S/D portions 110_{L} and 110_{R} can be substantially asymmetric to each other with respect to cross-sectional line E-E, where lateral S/D portions 110_{L} and 110_{R} can both include convex sidewalls with different radius of curvature between each other. For example, referring to FIG. 1E, for a cross-sectional line (e.g., cross-sectional line H-H) substantially parallel to substrate 106 and crossing S/D region 110 (e.g., S/D region 110₃), S/D region 110₃'s side surfaces 113 and 115 can both include convex sidewalls proximate to the cross-sectional line (e.g., cross-sectional line H-H), while lateral width W₂ between side surface 115's convex sidewall and fin structure 108's side surface 108_{R} (e.g., point N) can be narrower than lateral width W₁ between side surface 113's convex sidewall and fin structure 108's side surface 108_{L} (point M).

In some embodiments, for a cross-sectional line (e.g., cross-sectional line H-H) substantially parallel to substrate 106 and crossing S/D region 110 (e.g., S/D region 110₃), S/D region 110₃'s side surfaces 113 and 115 can both include convex sidewalls proximate to the cross-sectional line (e.g., cross-sectional line H-H), where a ratio of side surface 115's convex sidewall's radius of curvature to side surface 113's convex sidewall's radius of curvature can be from about 1.1 to about 10.0, from about 1.1 to about 5.0, from about 1.1 to about 3.0, from about 1.1 to about 2.0, from about 1.2 to about 1.8, from about 1.25 to about 1.5, or from about 1.25 to about 1.4. In some embodiments, side surface 115's convex sidewall can be laterally (e.g., in the y-direction) positioned between fin structure 108's side surfaces 108_{L} and 108_{R}, where lateral width W₂ can be less than about 10 nm. By way of example and not limitation, the above-noted asymmetric convex sidewalls in S/D region 110 can be achieved by method 200 (discussed below).

In some embodiments, the shapes of lateral S/D portions 110_{L} and 110_{R} can be substantially asymmetric to each other with respect to cross-sectional line E-E, where one of lateral S/D portions 110_{L} and 110_{R} can include a shoulder structure between top surface 111 and side surfaces 113 or between top surface 111 and side surface 115. For example, referring to FIG. 1F, S/D region 110₃'s side surfaces 113 and 115 can both include convex sidewalls proximate to cross-sectional line H-H, where side surface 115 can further include a shoulder structure 117 connecting the side surface 115's convex sidewall and top surface 111. In some embodiments, a lateral width W₅ between shoulder structure 117 and fin structure 108's side surface 108_{R} (e.g., point N) can be narrower than lateral width W₂ between side surface 115's convex sidewall and fin structure 108's side surface 108_{R} (point N). In some embodiments, a ratio of lateral width W₅ to lateral width W₂ can range from about 0 to about 0.8, from about 0 to about 0.6, or from about 0 to about 0.4. In some embodiments, lateral width W₅ can be from about 2 nm to about 15 nm. In some embodiments, for a cross-sectional line (e.g., cross-sectional line I-I) substantially parallel to substrate 106 and crossing S/D region 110 (e.g., S/D region 110₃), S/D region 110₃'s side surfaces 113 can include a slanting sidewall proximate to the cross-sectional line (e.g., cross-sectional line H-H), while S/D region 110₃'s side surfaces 115 can include shoulder structure 117 proximate to the cross-sectional line (e.g., cross-sectional line H-H). By way of example and not limitation, the above-noted shoulder structure 117 can be achieved by the later discussed method 200 (discussed below).

In some embodiments, the shapes of lateral S/D portions 110_{L} and 110_{R} can be substantially asymmetric to each other with respect to cross-sectional line E-E, where one of lateral S/D portions 110_{L} and 110_{R} can include a convex sidewall and the other can include a concave sidewall. For example, referring to FIG. 1G, S/D region 110₃'s side surfaces 113 and 115 can respectively include a convex sidewall and a concave sidewall proximate to cross-sectional line H-H. In some embodiments, side surface 115's concave sidewall can be laterally (e.g., in the y-direction) positioned between fin structure 108's side surfaces 108_{L} and 108_{R}. In some embodiments, side surface 115's concave sidewall can be laterally (e.g., in the y-direction) formed over fin structure 108's side surface 108_{L}.

In some embodiments, S/D region 110 can be formed over a multiple fin structures 108, where one of S/D region 110's side surfaces can have a reduced side extension (e.g., along the y-direction) compared to that of other S/D regions 110. For example, referring to FIG. 1H, S/D region 110₃ can be formed merging on a multiple fin structures 108 (e.g., fin structures 108₁ and 108₂). The multiple fin structures 108 can have an outermost fin structure 108 (e.g., fin structure 108₁) having surface 108_{L}, and another outermost fin structure 108 (e.g., fin structure 108₂) having surfaces 108_{R}. Surface 108_{L} can be proximate to S/D region 110₃'s side surface 113. Similarly, surface 108_{R} can be proximate to S/D region 110₃'s side surface 115. Cross-sectional line F-F can cross points R and S respectively over side surfaces 108_{L} and 108_{R}. Accordingly, a lateral width W₇ between S/D region 110₃'s lateral S/D portion 110_{R}'s side surface 115 and the multiple fin structures 108's outermost side surface 108_{R} (e.g., point S) can be narrower than a lateral width W₆ between S/D region 110₃'s lateral S/D portion 110_{L}'s side surface 113 and the fin structure 108's another outermost side surface 108_{L} (point R). In some embodiments, a difference between lateral widths W₆ and W₇ can be from about 1 nm to about 30 nm, from about 3 nm to about 20 nm, or from about 5 nm to about 20 nm. In some embodiments, a ratio of lateral width W₇ to lateral width W₆ can range from about 0.05 to about 0.8, from about 0.05 to about 0.6, or from about 0.05 to about 0.4. Further, similar to the embodiments in FIGS. 1C-1G, the shapes of both sides of merged S/D region 110₃ can be substantially asymmetric to each other. For example, S/D region 110₃ shown in FIG. 1H can have side surfaces 113 and 115 (including convex sidewalls) with different radii of curvature from each other. In some embodiments, one of side surfaces 113 and 115 can include a shoulder structure, while the other does not. In some embodiments, one of side surfaces 113 and 115 can include a convex sidewall, while the other can include a concave sidewall. By way of example and not limitation, the above-noted lateral extension width difference/ratio and shape asymmetry for S/D region 110₃ can be achieved by method 200 (discussed below).

Referring to FIG. 1A, FET 102 can further include S/D contact 124 formed over S/D region 110 to electrically connect the underlying S/D region 110 to other elements of the integrated circuit (not shown in FIG. 1A). S/D contact 124 can include a silicide layer and a conductive region over the silicide layer (not shown in FIG. 1A). The silicide layer can include metal silicide and can provide a low resistance interface between the conductive regions and the underlying S/D region 110. Examples of metal used for forming the metal silicide can be Co, Ti, and Ni. The conductive region can include conductive materials, such as W, Al, and Co. The conductive region can have an average horizontal dimension (e.g., width in the y-direction) in a range from about 15 nm to about 25 nm and can have an average vertical dimension (e.g., height in the z-direction) in a range from about 400 nm to about 600 nm. In some embodiments, at least one conductive liner (not shown) can be disposed between the silicide layer and the conductive region. The conductive liner can be a diffusion barrier and can include a single layer or a stack of conductive materials, such as TiN, Ti, Ni, TaN, Ta, and a combination thereof. In some embodiments, the conductive liner can act as an adhesion-promoting-layer, a glue-layer, a primer-layer, a protective-layer, and/or a nucleation-layer. The conductive liner can have a thickness in a range from about 1 nm to about 2 nm, according to some embodiments. Based on the disclosure herein, other materials and dimensions for the conductive liner, the silicide layer, and the conductive region are within the scope and spirit of this disclosure.

Referring to FIGS. 1A and 1B, semiconductor device 100 can further include etch stop layer (ESL) 116, interlayer dielectric (ILD) layer 118, and shallow trench isolation regions 138. ESL 116 can protect gate structure 112 and/or S/D region 110. This protection can be provided, for example, during formation of ILD layer 118 and/or S/D contact 124. ESL 116 can be disposed on surfaces of S/D region 110 and/or sidewalls of gate spacers 114. In some embodiments, ESL 116 can include, for example, silicon nitride, silicon oxide, silicon oxynitride, silicon carbide, silicon carbo-nitride, boron nitride, silicon boron nitride, silicon carbon boron nitride, or a combination thereof. In some embodiments, ESL 116 can have a thickness ranging from about 3 nm to about 30 nm. Other materials and thicknesses for ESL 116 are within the scope and spirit of this disclosure.

ILD layer 118 can be disposed on ESL 116 and can include a dielectric material deposited using a deposition method suitable for flowable dielectric materials (e.g., flowable silicon oxide, flowable silicon nitride, flowable silicon oxynitride, flowable silicon carbide, or flowable silicon oxycarbide). For example, flowable silicon oxide can be deposited using flowable CVD (FCVD). In some embodiments, the dielectric material can be silicon oxide. In some embodiments, ILD layer 118 can have a thickness from about 50 nm to about 200 nm. Other materials, thicknesses, and formation methods for ILD layer 118 are within the scope and spirit of this disclosure.

Referring to FIGS. 1A-1D, semiconductor device 100 can further include an isolation structure 104 disposed between two horizontally (e.g., in the y-direction) adjacent S/D regions 110. For example, isolation structure 104 can be disposed between S/D regions 110₁ and 110₂. In some embodiments, isolation structure 104 can be further formed protruding into an portion of STI region 138. In some embodiments, isolation structure 104 can be further formed through STI region 138 and protruding into an portion of substrate 106. Isolation structure 104 can include one or more layers, in which each layer can includes an insulating material, such as silicon oxide, silicon nitride, a high-k dielectric, and a low-k dielectric, to electrically isolate S/D regions 110 placed at opposite sides of isolation structure 104. In some embodiments, isolation structure 104 and ESL 116 can be made of different insulating materials. In some embodiments, isolation structure 104 and ESL 116 can be made of insulating materials having different etching selectivities. In some embodiments, isolation structure 104 and STI region 138 can be made of different insulating materials. In some embodiments, isolation structure 104 and STI region 138 can be made of insulating materials having different etching selectivities. In some embodiments, as shown in FIGS. 1C and 1D, isolation structure 104 can be in contact with portions of ESL 116, where the portions of ESL 116 can be further in contact with S/D region 110. In some embodiments, isolation structure 104 can extend through gate structure 112 (e.g., along the x-axis) and be disposed over STI region 138. In some embodiments, isolation structures 104 can electrically isolate gate structures 112 traversed through by isolation structure 104. A segment of gate structure 112 associated with FETs 102 on fin structure 108₁ can be electrically insulated from another segment of gate structure 112 associated with FETs 102 on fin structure 108₂.

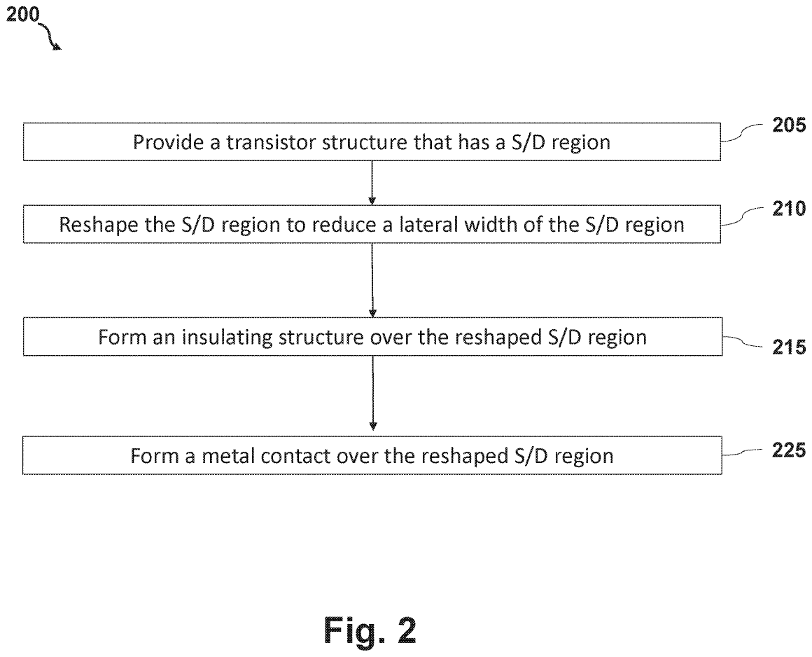

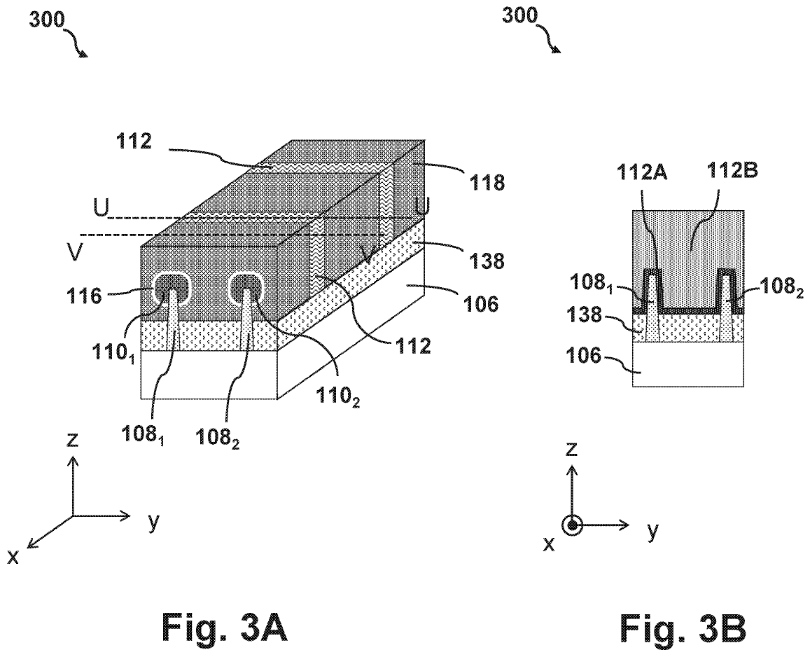

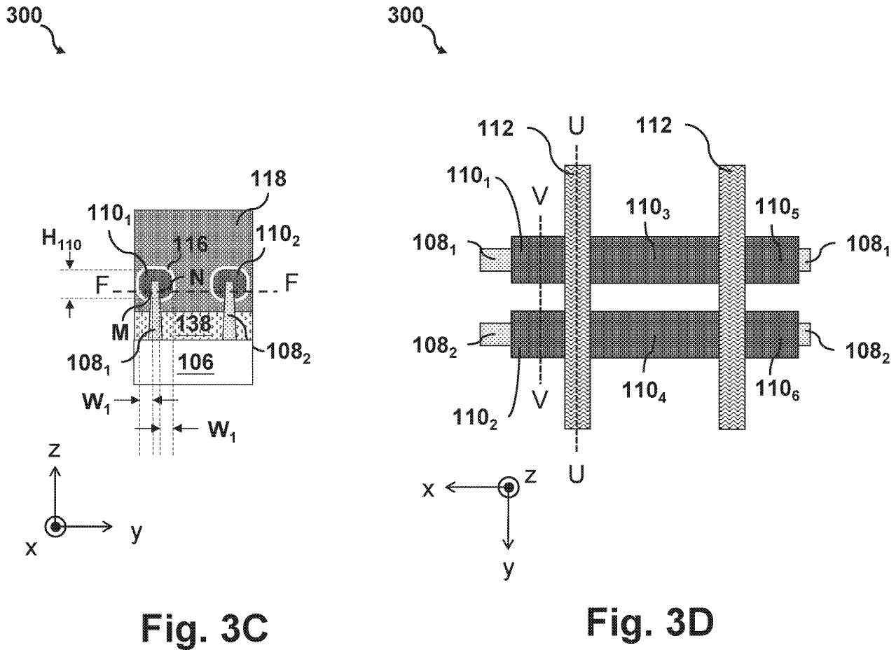

FIG. 2 is a flow diagram of a method 200 for fabricating semiconductor device 100, according to some embodiments. For illustrative purposes, the operations illustrated in FIG. 2 will be described with reference to the example fabrication process for fabricating semiconductor device 100 as illustrated in FIGS. 3A-3D, 4A-9A, and 4B-9B. FIG. 3A is an isometric view of semiconductor device 100 at various stages of its fabrication, according to some embodiments. FIGS. 3B and 4A-9A are cross-sectional views along line U-U of structures of FIG. 3A at various stages of its fabrication, according to some embodiments. FIGS. 3C and 4B-9B are cross-sectional views along line V-V of structures of FIG. 3A at various stages of its fabrication, according to some embodiments. FIG. 3D is a top-view of FIG. 3A at various stages of its fabrication, according to some embodiments. Operations can be performed in a different order or not performed depending on specific applications. Method 200 may not produce a complete semiconductor device 100. Accordingly, it is understood that additional processes can be provided before, during, and/or after method 200, and that some other processes may only be briefly described herein. Further, the discussion of elements in FIGS. 1A-1H, 3A-3D, 4A-9A, and 4B-9B with the same annotations applies to each other, unless mentioned otherwise.

Referring to FIG. 2, in operation 205, a transistor structure with one or more S/D regions is provided. For example, FIGS. 3A-3D show a semiconductor device 300 with one or more FETs 102 having S/D regions 110. By way of example and not limitation, a process of forming semiconductor device 300 can include forming fin structure 108 on substrate 106, forming STI region 138 adjacent to fin structure 108, forming gate structure 112 traversing through fin structure 108, and forming S/D regions 110 over fin structure 108 and adjacent to gate structure 112. In some embodiments, S/D region 110 can be grown by (i) CVD, such as low pressure CVD (LPCVD), atomic layer CVD (ALCVD), ultrahigh vacuum CVD (UHVCVD), reduced pressure CVD (RPCVD), and any other suitable CVD technique; (ii) molecular beam epitaxy (MBE) processes; (iii) any suitable epitaxial process; or (iv) a combination thereof. In some embodiments, S/D region 110 can be in-situ doped during the epitaxial growth process using p-type precursors (e.g., diborane or boron trifluoride) or n-type precursors (e.g., phosphine or arsine). In some embodiments, the resulting S/D region 110 can have a height H₁₁₀ ranging from about 15 nm to about 80 nm, from about 25nm to about 65nm, or from about 25 nm to about 50 nm. In some embodiments, the resulting S/D region 110 can have a substantially equal lateral width W₁ at both sides of fin structure 108. The process of forming semiconductor device 300 can further include forming ESL 116 over S/D region 110 and forming ILD layer 118 over ESL 116 and a portion of fin structure 108 not covered by gate structure 112. Based on the disclosure herein, other formation methods for semiconductor device 300 are within the spirit and scope of this disclosure.

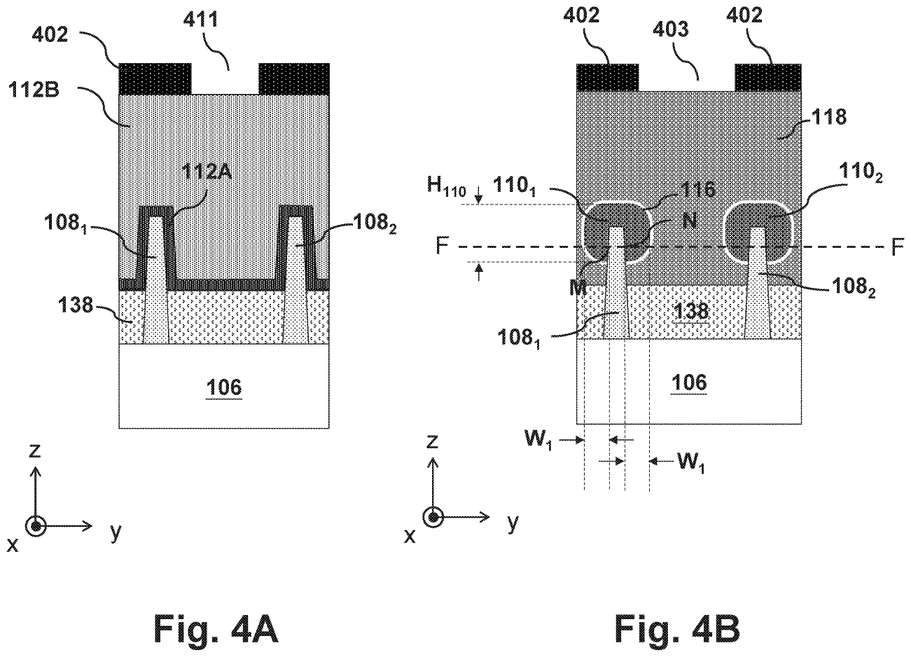

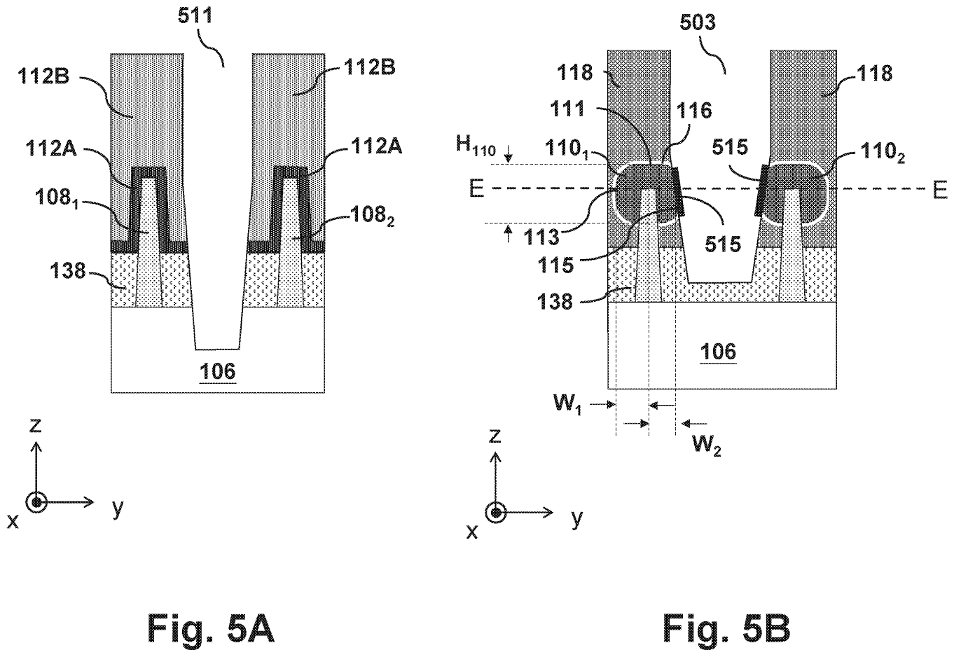

Referring to FIG. 2, in operation 210, S/D region 110 is reshaped to reduce its lateral width. For example, as shown in FIG. 5B, S/D region 110₁ can be reshaped to reduce its lateral width from W₁ to W₂ at side surface 115, as described with reference to FIGS. 4A-4B and 5A-5B. In some embodiments, a process of reshaping S/D region 110 can include (i) patterning a mask layer 402 (shown in FIGS. 4A and 4B) on substrate 106 and (ii) removing S/D region 110 through the patterned mask layer 402 to reduce S/D region 110's lateral width from W₁ to W₂ (shown in FIGS. 5A and 5B).

By way of example and not limitation, mask layer 402 can be a thin film including silicon oxide or silicon nitride formed, for example, using a deposition process. In some embodiments, as shown in FIG. 4B, the process of patterning mask layer 402 can form an opening 403 over S/D regions 110 and ILD layer 118 using a lithography process and an etching process. In some embodiments, opening 403 can vertically overlap with portions of underlying S/D regions 110. In some embodiments, as shown in FIG. 4A, the process of patterning mask layer 402 can further form an opening 411 between two adjacent fin structures 108 to expose gate structure 112.

Referring to FIG. 5B, the process of removing S/D region 110 can include forming a recess 503 through ILD layer 118, a portion of ESL 116 that covers S/D region 110, a portion of S/D region 110 under opening 403, and a portion of STI region 138 by using an etch-back process. Therefore, recess 503 can expose side surface 115 of another portion of S/D region 110 that is outside opening 403 (e.g., under mask layer 402). Namely, the etch-back process can etch a side of S/D region 110 to expose side surface 115, while an opposite side (e.g., side surface 113) of S/D region 110 can be masked under mask layer 402. Accordingly, after the etch-back process, S/D region 110's lateral width can be decreased from width W₁ to width W₂. In some embodiments, the etch-back process can etch ILD layer 118 and S/D region 110 with a substantially equal etching rate, where the resulting recess 503 can expose side surface 115 that can include a substantially straight slanting sidewall (shown in FIG. 1C) after the etch-back process. In some embodiments, the etch-back process can be orientation dependent, where the resulting recess 503 can expose side surface 115 that can include a convex sidewall (shown in FIG. 1E) after the etch-back process. In some embodiments, the etch-back process can be orientation independent, where the resulting recess 503 can expose side surface 115 that can include a concave sidewall (shown in FIG. 1G) after the etch-back process. In some embodiments, the etch-back process can etch ILD layer 118 with an etching rate faster than that for S/D region 110, where the resulting recess 503 can expose side surface 115 that can include a shoulder structure (shown in FIG. 1F) after the etch-back process. In some embodiments, the process of removing S/D region 110 can include maintaining S/D region 110's height H₁₁₀ after the etch-back process. For example, mask layer 502 can mask S/D region 110's top surface 111, while forming recess 503 with the etch-back process. Accordingly, S/D region 110's height H₁₁₀ can remain intact after the etch-back process. By way of example and not limitation, the etch-back process can include a dry etching process using suitable etch gas, such as an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), and an iodine-containing gas,. In some embodiments, after the etch-back process, an interfacial layer 515 can be formed over the exposed side surface 115. The interfacial layer 515 can include a reaction product by intermixing material of S/D region 110 and the etching gas's elements during the etch-back process. In some embodiments, interfacial layer 515 can include iodine, chlorine, fluorine, or bromine.

In some embodiments, the process of removing S/D region 110 can further include splitting gate structure 112 connecting between two adjacent fin structures 108. For example, referring to FIG. 5A, the process of removing S/D region 110 can also form a recess 511 through gate dielectric layer 112A and gate electrode 112B between fin structures 108₁ and 108₂. In some embodiments, recess 511 can be further formed through STI region 138 and portion of substrate 106.

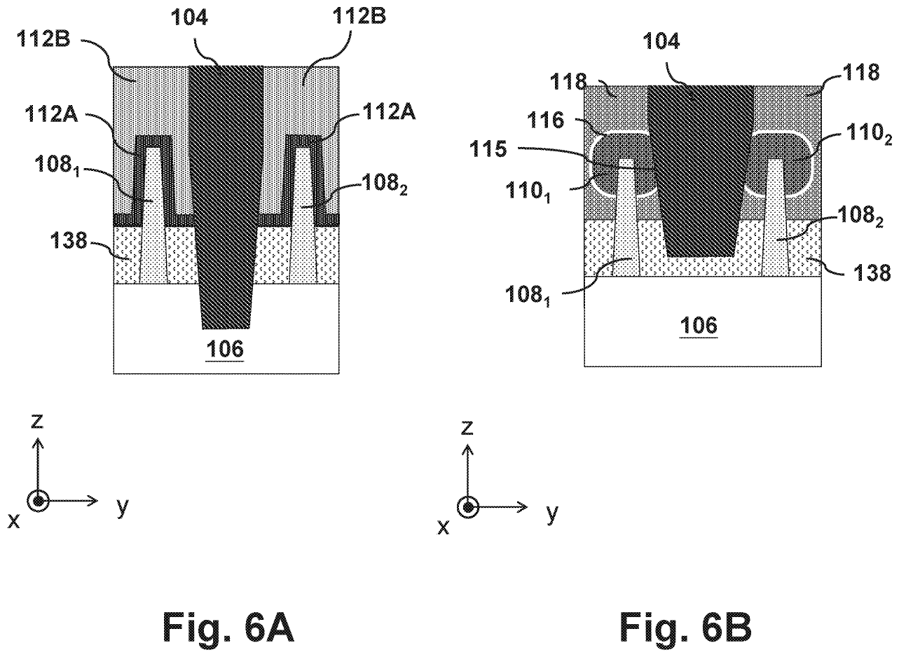

Referring to FIG. 2, in operation 215, an insulating structure is formed over the reshaped S/D region. For example, as shown in FIG. 6B, isolation structure 104 can be formed over S/D regions 110₁ and 110₂, as described with reference to FIGS. 6A and 6B. By way of example and not limitation, a process of forming isolation structure 104 can include (i) depositing a layer stack of insulating material over recess 503 using a suitable deposition process, such as atomic layer deposition (ALD), chemical vapor deposition (CVD), flowable CVD (FCVD), high-density-plasma (HDP) CVD, sub-atmospheric CVD (SACVD), and high aspect-ratio process (HARP) and (ii) chemical mechanical polishing (CMP) the layer stack of insulating material to coplanarize isolation structure 104 and ILD layer 118. In some embodiments, isolation structure 104 can be in contact with ESL 116 that surrounds S/D region 110. In some embodiments, isolation structure 104 can be in contact with side surface 115 of the reshaped S/D region 110. In some embodiments, isolation structure 104 can be formed between two adjacent reshaped S/D region 110. In some embodiments, as shown in FIG. 6A, the process of forming isolation structure 104 can further include depositing the layer stack of insulating material over recess 511, and CMP the layer stack of insulating material to form isolation structure to isolate two adjacent gate structures 112.

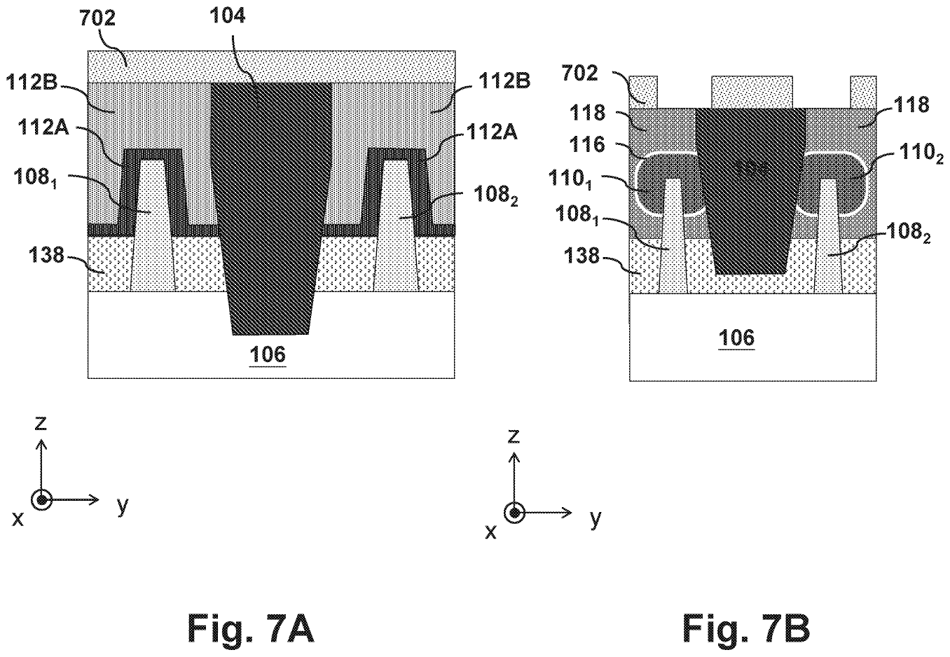

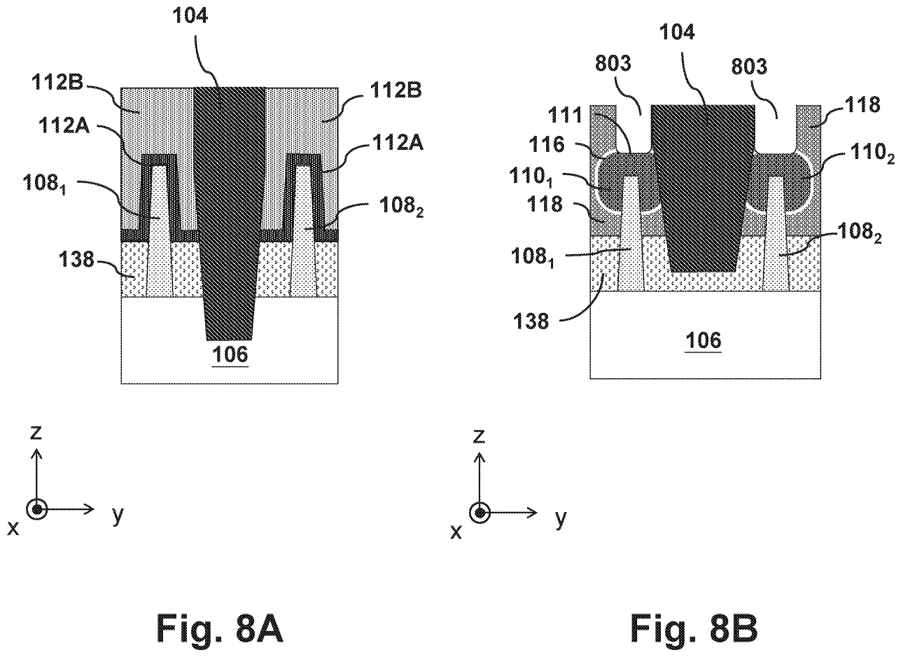

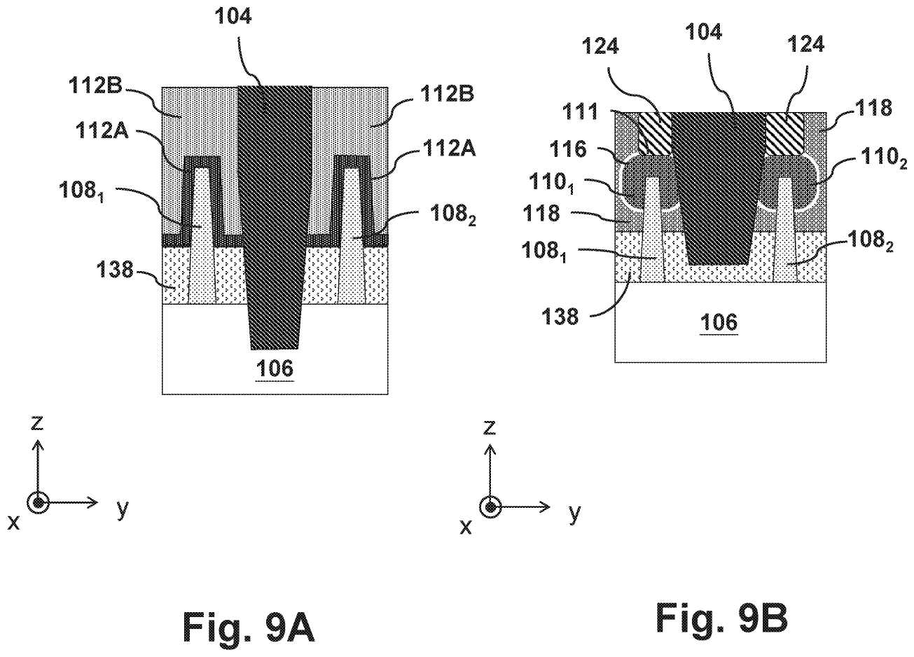

Referring to FIG. 2, in operation 220, a metal contact is formed over the reshaped S/D region 110. For example, as shown in FIG. 9B, S/D contact 124 can be formed the reshaped S/D 110's top surface 111 as described in reference to FIGS. 7A-9A and 7B-9B. By way of example and not limitation, a process of forming S/D contact 124 can include (i) forming a patterned mask layer 702 (shown in FIGS. 7A and 7B) to expose a portion of ILD layer 118 above S/D regions 110 using a lithography process, (ii) removing ILD layer 118 and ESL 116 through patterned mask layer 702 to form a recess 803 (shown in FIGS. 8A and 8B) that exposes S/D regions 110, (iii) depositing one or more conductive materials in recess 803 using a suitable deposition process (e.g., CVD, ALD, PVD, or e-beam evaporation), and (iv) polishing the deposited one or more conductive materials using a CMP process to form S/D contact 124 (shown in FIG. 9B). By way of example and not limitation, the one or more conductive materials for S/D contact 124 can include a metal silicide, a conductive nitride liner, or a metallic material such as W, Al, Cu, Ti, and Co. Accordingly, as shown in FIG. 9B, the resulting S/D contact 124 can be coplanarized with isolation structure 104 and ILD layer 118. Further, as shown in FIG. 9B, the resulting S/D contact 124 can be in contact with its underlying S/D regions 110's top surface 111.

Further, following operating 220, an interconnect structure (not shown in FIGS. 9A and 9B) can be formed over S/D contact 124 to provide electrical routing for semiconductor device 100. By way of example and not limitation, a process of forming the interconnect structure can include (i) blanket depositing an insulating stack over the structure of FIGS. 9A and 9B via a suitable deposition process, such as a CVD process, a PECVD process, a PVD process, and a ALD process, (ii) forming one or more vias (not shown in FIGS. 9A and 9B) through the deposited insulating stack using a lithography process and an etching process, and (iii) filling the one or more vias with one or more conductive material to form trench conductor layer (not shown in FIGS. 9A and 9B) using a suitable deposition process (e.g., CVD, ALD, PVD, or e-beam evaporation) and a polishing process (e.g., a CMP process). In some embodiments, the resulting trench conductor layer can be in contact with S/D contact 124. In some embodiments, the resulting trench conductor layer can be in contact with gate electrode 112B. In some embodiments, the process of forming the interconnect structure can further include depositing a layer of conductive material (not shown in FIGS. 9A and 9B) over the trench conductor layer using a suitable deposition process (e.g., CVD, ALD, PVD, or e-beam evaporation), where the layer of conductive material can provide an interconnect routing for the interconnect structure.

The present disclosures provides an exemplary S/D region structure and a method for forming the same. The S/D region can have a reduced lateral volume to minimize the parasitic capacitance between the gate terminal and the source/drain terminal of a transistor. In some embodiments, the S/D region can be grown on a fin structure, where the S/D region can be subsequently reshaped to reduce a lateral width at one side. In some embodiments, the reshaped S/D region can be asymmetric with respect to a midline that bisects the fin structure. A benefit of the reshaped S/D structure, among others, is to reduce the parasitic capacitance contributed from S/D region's lateral extension while maintaining a low contact resistance, thus enhancing the transistor's performance.

In some embodiments, a method for forming a semiconductor structure can include forming a fin structure over a substrate. The method can further include forming, over the fin structure, a source/drain region with a lateral width. The method can further include removing a portion of the source/drain region to decrease the lateral width of the source/drain region, and forming an insulating stack over the source/drain region with the decreased lateral width.

In some embodiments, a method for forming a semiconductor structure can include forming first and second fin structures over a substrate, forming a source/drain region over sidewalls of the first and second fin structures, removing a first portion of the source/drain region to expose a second portion of the source/drain region, and forming an insulating stack over the second portion of the source/drain region.

In some embodiments, a semiconductor structure can include a substrate, an insulating stack formed over the substrate, a vertical structure formed through the insulating stack, a source/drain region formed over the vertical structure, and an isolation structure formed adjacent to the source/drain region and protruding the insulating stack. The source/drain region can include a first side surface and a second side surface. A lateral separation between the first side surface and the vertical structure can be greater than an other lateral separation between the second side surface and the vertical structure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a fin structure on a substrate;
a source/drain (S/D) region on the fin structure, wherein the S/D region comprises an upper portion and a lower portion, wherein a width of the upper portion is less than a width of the lower portion; and
an isolation structure protruding into the S/D region, wherein the isolation structure is in contact with a concave surface of the upper portion and isolated from the lower portion.

2. The structure of claim 1, wherein the isolation structure comprises a first portion and a second portion on the first portion, and wherein a width of the second portion is greater than a width of the first portion.

3. The structure of claim 2, wherein the second portion is in contact with the S/D region, and wherein the second portion is separated from the S/D region.

4. The structure of claim 2, further comprising a third portion on the second portion, wherein a width of the third portion is less than a width of the second portion.

5. The structure of claim 1, further comprising an interlayer dielectric (ILD) layer between the S/D region and the isolation structure.

6. The structure of claim 1, wherein the ILD layer is in contact with a convex surface of the S/D region and a flat surface of the isolation structure.

7. The structure of claim 1, wherein a bottom surface of the isolation structure is below the S/D region.

8. A structure, comprising:
a vertical structure on a substrate;
a source/drain (S/D) region over the vertical structure; and
an isolation structure extending parallel to the vertical structure, wherein the isolation structure is in contact with the S/D region, wherein the isolation structure comprises an upper portion, a middle portion, and a lower portion, and wherein a width of the middle portion is greater than widths of the upper and lower portions.

9. The structure of claim 8, wherein the middle portion is in contact with a concave surface of the S/D region.

10. The structure of claim 8, wherein the lower portion is separated from the S/D region.

11. The structure of claim 8, wherein a bottom surface of the isolation structure is below the S/D region.

12. The structure of claim 8, further comprising an interlayer dielectric (ILD) layer between vertical structure and the isolation structure.

13. The structure of claim 12, wherein the S/D region is in contact with a concave surface of the ILD layer.

14. The structure of claim 8, further comprising an S/D contact on the S/D region and in contact with the upper portion of the isolation structure.

15. A structure, comprising:
first and second fin structures on a substrate;
first and second source/drain (S/D) structures on the first and second fin structures, respectively; and
an isolation structure between the first and second fin structures and in contact with concave side surfaces of the first and second S/D structures, wherein a bottom surface of the isolation structure is below the first and second S/D structures.

16. The structure of claim 15, wherein the isolation structure comprises:
a first portion in contact with the concave side surfaces of the first and second S/D structures; and
a second portion under the first portion, wherein the second portion is separated from the first and second fin structures.

17. The structure of claim 16, wherein a width of the first portion is greater than a width of the second portion.

18. The structure of claim 16, wherein the isolation structure further comprises a third portion on the first portion, and wherein a width of the third portion is less than the width of the first portion.

19. The structure of claim 18, further comprising a first S/D contact and a second S/D contact on the first S/D structure and the second S/D structure, respectively, wherein the first and second S/D contacts are in contact with the third portion of the isolation structure.

20. The structure of claim 15, further comprising:
an S/D contact on the first and second S/D structures; and
a gate structure on the first and second S/D structures and between the S/D contact and the isolation structure.
